(19) United States
(12) Patent Application Publication
(10) Pub. No.: US 2012/0229132 A1
(43) Pub. Date: Sep. 13, 2012

(54) STACKED TYPE MAGNETIC FIELD DETECTION SENSOR

(75) Inventors: Sang Gyu Park, Seoul (KR); Young Sik HUR, Gyunggi-do (KR); Kyung Uk KIM, Gyunggi-do (KR)

(73) Assignee: SAMSUNG ELECTRO-MECHANICS CO., LTD., Gyunggi-do (KR)

(21) Appl. No.: 13/409,970

(22) Filed: Mar. 1, 2012

(30) Foreign Application Priority Data
Mar. 8, 2011 (KR) 1020110020562

(51) Int. Cl. G01R 33/06

(52) U.S. Cl. 324/251

(57) ABSTRACT

Disclosed herein is a stacked type magnetic field sensor. The stacked type magnetic field detection sensor includes a vertical hall device including a first substrate of a thickness having a first gate length on which a first circuit pattern in a vertical direction is formed so as to sense magnetic field horizontally input and converting the magnetic field into a voltage signal; and a signal processing circuit unit including a second substrate having a thickness having a second gate length to receive the voltage signal so as to detect a magnitude in the magnetic field according to the magnitude in the voltage and detecting the magnitude in the magnetic field by processing the voltage signal through the plurality of second circuit patterns. By this configuration, magnetic detection sensitivity can be improved, the magnetic field detection sensor can be miniaturized, and IC manufacturing costs can be saved.

### CROSS REFERENCE TO RELATED APPLICATION

This application claims the benefit of Korean Patent Application No. 10-2011-0020562, filed on Mar. 8, 2011, entitled “Stacked Type Magnetic Field Sensor”, which is hereby incorporated by reference in its entirety into this application.

### BACKGROUND OF THE INVENTION

1. Technical Field

The present invention relates to a stacked type magnetic field detection sensor.

2. Description of the Related Art

In recent years, various products using a sensing technology in a wide range of fields have been released. Among others, a small proximity sensor field may be largely classified into a switching sensor differentiating a magnitude in magnetic field and a current measurement sensor outputting a magnitude in a magnetic field as linear voltage.

First, the switching sensor is applied with any external magnetic field to differentiate the magnitude in magnetic field. In this case, the switching sensor uses a method for vertically applying magnetic field from above or below a sensor IC so as to be most suitable for sensing characteristics and detecting the magnetic field.

On the other hand, the current measurement sensor detects magnetic field generated by applying current to a current wire to measure strength of current. For example, an example of the current measurement sensor may include resistive shunts, current transformers (CT), a magnetic sensor IC, or the like.

Meanwhile, the resistive shunts is inexpensive but is vulnerable to surge current or spike voltage due to a sudden change in input and cannot be integrated in a system level.

The CT is configured of a magnetic coupled coil and thus, separates two coils from each other in a DC form, such that the CT cannot measure the DC current.

The magnetic sensor ICs are expensive, but can measure a DC signal that is a disadvantage of the CT and can be implemented by a CMOS unlike the resistive shunts, such that the magnetic sensor ICs facilitate the system integration and have not been affected by the surge current or the spike voltage. Therefore, the magnetic sensor ICs have been prevalently used in recent.

In addition to the magnetic sensor ICs, the current measurement sensor may generate a large amount of output voltage as current amount is large and the current wire approaches the sensor IC.

In this case, since the current is a defined value, a distance between the sensor IC and the current wire needs to be minimized so as to maximize sensitivity while minimizing the external influence.

In order to minimize the distance between the sensor IC and the current wire, the current wire needs to be disposed above or below the sensor IC, thereby obtaining an optimal output value.

In other words, when the current wire passes above or below the sensor IC, the magnetic field induced due to the current flowing in the current wire is horizontally input, unlike the switching sensor.

Detecting the magnetic field input vertically to a hall sensor has a better output value in terms of semiconductor processes and characteristics than detecting the magnetic field horizontally input. Therefore, more easily and accurately detecting the magnetic field horizontally input using any method has been considered as an important issue.

In order to detect the horizontal magnetic field, two of various types of technology performed in the prior art have been mainly used.

One of the methods is a method for vertically changing the external horizontal magnetic field within a package and detecting the changed magnetic field by the magnetic field sensing IC and the other one of the methods is a method for adding a ferromagnetic layer during the semiconductor process to convert the magnetic field horizontally input into vertical magnetic field by the ferromagnetic layer without changing an external appearance thereof and detecting the vertical magnetic field by the magnetic field sensing IC.

However, when a thickness of the semiconductor substrate (for example, a wafer) is too thin, a performance of detecting the external magnetic field is degraded. Therefore, the magnetic field detection sensitivity is improved only when the thick substrate is used.

Further, the process applied to the thick substrate increases a semiconductor minimum gate length and therefore, a circuit of a signal processing portion other than a vertical hall device also needs to be designed by the process applied to a long gate, which causes bad outcomes in terms of the overall chip size and the IC costs.

### SUMMARY OF THE INVENTION

The present invention has been made in an effort to provide a stacked type magnetic field detection sensor formed by stacking two substrates formed in response to each gate length.

According to a preferred embodiment of the present invention, there is provided a stacked type magnetic field detection sensor, including: a vertical hall device including a first substrate of a thickness having a first gate length on which a first circuit pattern in a vertical direction is formed so as to sense magnetic field horizontally input and converting the magnetic field passing through circuit patterns in the vertical direction into a voltage signal; and a signal processing circuit unit including a second substrate having a thickness having a second gate length on which a plurality of second circuit patterns are formed, to receive the voltage signal by stacking the vertical hall device thereon so as to detect a magnitude in the magnetic field according to the magnitude in the voltage and detecting the magnitude in the magnetic field by processing the voltage signal through the plurality of second circuit patterns.

The first gate length may be 250 to 350 nm.

The second gate length may be 90 to 180 nm.

The first substrate may be made of a ferromagnetic material.

The plurality of second circuit patterns may include: a power supply circuit supplying power supply voltage; a regulator stabilizing the power supply voltage supplied from the power supply circuit; an oscillator supplied with the stabilized power supply voltage from the regulator to generate a clock signal having a period; and a chopping circuit receiving the voltage signal from the vertical hall device operated by being supplied with the stabilized power supply voltage from the regulator and the clock signal generated from the oscillator to amplify a magnitude in the voltage signal having a period of the clock signal; and an output load detecting output voltage according the voltage signal amplified from the chopping circuit to detect the magnitude in the magnetic field.

The plurality of second circuit patterns may further include a Schmitt trigger circuit that is mounted between the chopping circuit and the output load to compare the amplified voltage signal with a threshold value so as to output the voltage signal as a high signal or a low signal.

### BRIEF DESCRIPTION OF THE DRAWINGS

FIG. 1 is a cross-sectional view of a magnetic field detection sensor according to a preferred embodiment of the present invention;

FIG. 2 is a top view of the magnetic field detection sensor shown in FIG. 1;

FIG. 3 is a block diagram of the magnetic field detection sensor according to the preferred embodiment of the present invention; and

FIG. 4 is a diagram showing an example of cross section y-z of a vertical hall device taken along line A-A′ shown in FIG. 2.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In describing the present invention, a detailed description of related known functions or configurations will be omitted so as not to obscure the gist of the present invention.

Hereinafter, preferred embodiments of the present invention will be described in detail with reference to the accompanying drawings.

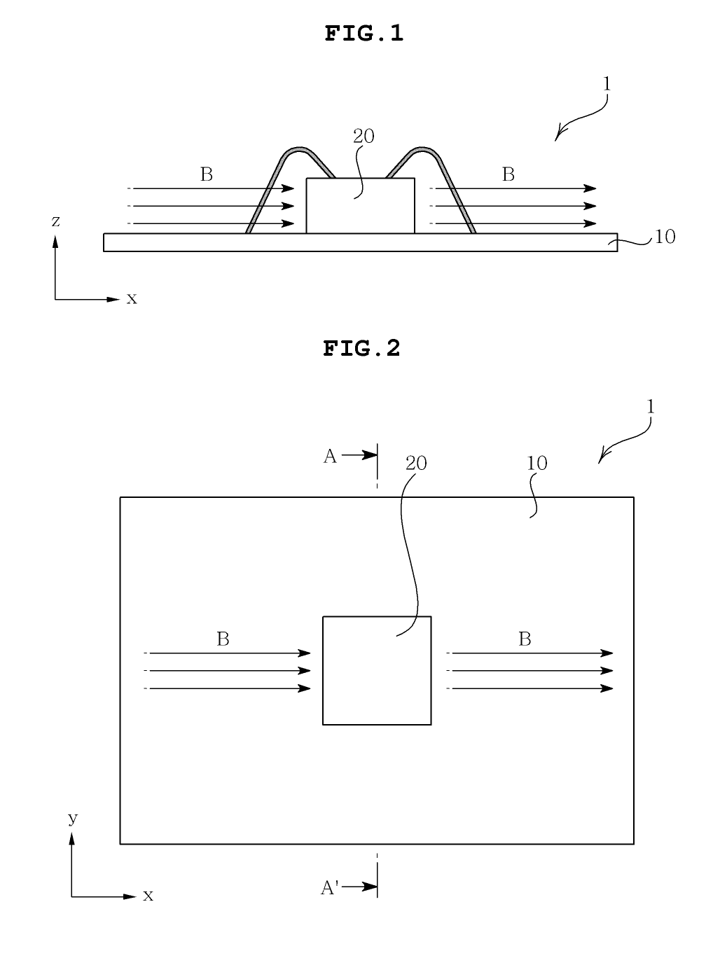

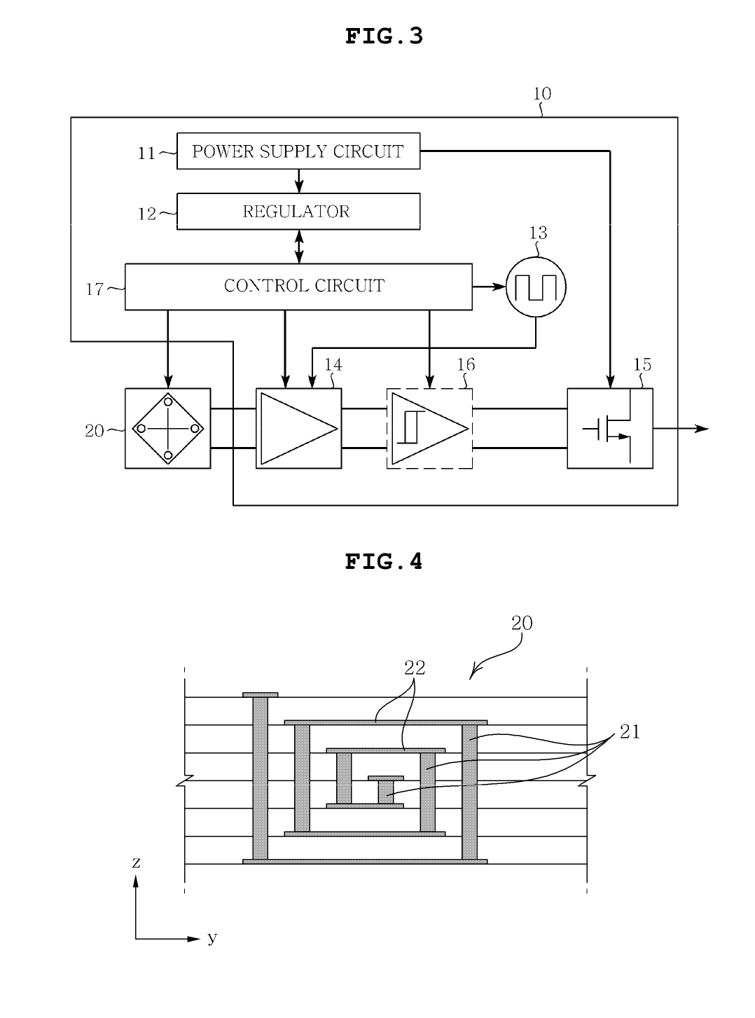

FIG. 1 is a cross-sectional view of a magnetic field detection sensor according to a preferred embodiment of the present invention, FIG. 2 is a top view of the magnetic field detection sensor shown in FIG. 1, FIG. 3 is a block diagram of the magnetic field detection sensor according to the preferred embodiment of the present invention, and FIG. 4 is a diagram showing an example of cross section y-z of a vertical hall device taken along line A-A′ shown in FIG. 2.

Referring to FIGS. 1 and 2, a stacked type magnetic field detection sensor 1 according to a preferred embodiment of the present invention includes a signal processing circuit unit 10 and a vertical hall device 20 and has a stacked structure in which the vertical hall device 20 is stacked on the signal processing circuit unit 10 by a chip stacking package (CSP) technology.

The signal processing circuit unit 10 operates the vertical hall device 20 when power supply voltage is supplied to receive a signal transferred from the vertical hall device 20, thereby processing the signal.

The signal processing circuit unit 10 is designed so as to form various patterns of circuits including an amplification circuit, a control circuit, or the like, for processing the signal on a substrate (for example, a first wafer) having an optimal area and thickness.

As described above, when the circuit pattern of the signal processing circuit unit 10 is generated, a gate length needs to be short so as to implement optimization.

Here, the gate length means a line width of the circuit pattern to be formed at the time of a circuit design and the area and thickness of the substrate are determined in response to the length of the gate.

That is, as the gate length is short, an area occupied by the circuit formed on the substrate is small and the thickness thereof is thin. On the other hand, as the gate length is long, an area occupied by the circuit to be formed on the substrate is increased and the thickness thereof is thick.

The area and thickness of the substrate are factors of increasing an IC cost in response thereto.

Therefore, the signal processing circuit unit 10 can be optimally designed as the substrate having the minimum area and thickness when the signal processing circuit unit 10 has a minimum gate length.

The signal processing circuit unit 10 may generally be designed by a semiconductor process of forming a plurality of circuit patterns on the substrate of a thickness having a gate length of 90 to 180 nm.

The vertical hall device 20 converts a magnitude in horizontal magnetic field B horizontally input to the device 20 into a voltage signal when the vertical hall device 20 is supplied with power supply voltage from the signal processing circuit unit 10 and then, transfers the converted voltage signal to the signal processing circuit unit 10.

The circuit pattern to be formed within the device 20 needs to be processed in a vertical direction as shown in FIG. 4 so as to efficiently detect the horizontal magnetic field B horizontally input to the device 20 and therefore, the vertical hall device 20 requires a substrate (for example, a second wafer) having a sufficient thickness.

Referring to FIG. 4, the vertical hall device 20 may be configured to include a plurality of vertical via holes 21 and a plurality of metal patterns 22 so that a circuit having a predetermined pattern for detecting the horizontal magnetic field B horizontally input to the device 20 is formed within the device 20 in a vertical direction.

As described above, at the time of generating the circuit patterns of the vertical hall device 20, the gate length needs to be long so as to implement the optimization.

Therefore, the vertical hall device 20 can be optimally designed as the substrate having the maximum area and thickness when the vertical hall device 20 has a maximum gate length. The vertical hall device 20 may generally be designed on the substrate of a thickness having the gate length of 350 nm by the semiconductor process forming the circuit patterns in a vertical direction as shown in FIG. 4.

In addition, the vertical hall device 20 may preferably use a substrate made of ferromagnetic substance so as to have larger magnetic field sensing sensitivity.

Meanwhile, an operation of the stacked type magnetic field detection sensor 1 according to the preferred embodiment of the present invention will be described in detail with reference to a block diagram shown in FIG. 3.

As shown in FIG. 3, the signal processing circuit unit 10 is configured to include a plurality of circuit patterns, such as a power supply circuit 11, a regulator 12, an oscillator 13, a chopping circuit 14, an output load 15, a control circuit 17, or the like.

The power supply circuit 11 supplies power supply voltage VDDE for operating each component of the signal processing circuit unit 10 and the vertical hall device 20.

For example, as the power supply voltage, alternating voltage between about 3V and 25V may be applied. However, in order to supply the alternating voltage to each component of the signal processing circuit unit 10 and the vertical hall device 20, the alternating voltage needs to be converted into predetermined power supply voltage.

The regulator 12 is stabilized so as to apply the power supply voltage VDDE supplied from the power supply unit 11 to each component of the signal processing circuit unit 10 and the vertical hall device 20.

For example, the regulator 12 stabilizes the alternating voltage between about 3V and 25V to apply a predetermined voltage of about 1.8V to each component of the signal processing circuit unit 10 and the vertical hall device 20.

The oscillator 13 generates a predetermined period of clock signal.

The chopping circuit 14 receives the voltage signal converted from the vertical hall device 20 and the clock signal generated from the oscillator 13 and amplifies the received voltage signal by a necessary size so as to be used as the signal for detecting the magnetic field B.

In this case, the amplified voltage signal may be amplified to have a period of the clock signal generated from the oscillator 13.

The output load 15 is a load device that detects the output voltage according to the voltage signal amplified through the chopping circuit 14 to detect the magnitude in the magnetic field B.

The magnitude in the horizontal magnetic field B input to the vertical hall device 20 is linearly proportional to the output voltage detected through the output load 15.

The control circuit 17 wholly controls the stacked type magnetic field detection sensor 1 according to the preferred embodiment of the present invention.

More specifically, when the control circuit 17 is supplied with the power supply voltage, the control circuit 17 performs a control to convert the horizontal magnetic field B sensed through the device into the voltage signal so as to detect the horizontal magnetic field B horizontally input to the device 20 by operating the vertical hall device 20 and transfer the converted voltage signal to the signal processing circuit unit 10.

Then, the control circuit 17 controls each component of the signal processing circuit unit 10 to amplify the voltage signal transferred from the vertical hole device 20 and then, linearly detect the magnitude in the horizontal magnetic field B by the output load 15.

In this case, the signal processing circuit unit 10 may further include a Schmitt trigger circuit 16 mounted between the chopping circuit 14 and the output load 15.

The Schmitt trigger circuit 16 detects the presence and absence of the magnetic field B rather than linearly detecting the magnetic field according to the voltage signal amplified from the chopping circuit 14.

For example, when a full swing range of the voltage signal converted according to the horizontal magnetic field B input through the vertical hall device 20 is 0 to 1V, the Schmitt trigger circuit 16 compares the voltage value of the voltage signal input from the chopping circuit 14 with a predetermined threshold value (for example, 0.8V) to output the voltage signal as a high signal when the voltage value is higher than the threshold value and output the voltage signal as a low signal when the voltage value is lower than the threshold value.

Therefore, the control circuit 17 determines that the horizontal magnetic field B horizontally input through the vertical hall device 20 is present when the high signal is output through the Schmitt trigger circuit 16 and determines that the horizontal magnetic field B horizontally input through the vertical hall device 20 is not present when the low signal is output through the Schmitt trigger circuit 16, thereby detecting the presence and absence of the magnetic field B.

As described above, when the stacked type magnetic field detection sensor 1 according to the preferred embodiment of the present invention requires different gate lengths for implementing the optimization of each component, that is, each of the signal processing circuit unit 10 and the vertical hall device 20, the signal process circuit unit 10 and the vertical hall device 20 are separately manufactured and stacked by the CSP technology, such that they can be designed to meet the gate length required for each component.

Further, the stacked type magnetic field detection sensor 1 according to the preferred embodiment of the present invention can save the IC manufacturing costs according to the substrate area and thickness by thickly manufacturing only the substrate of the vertical hall device 20 requiring the sufficient thick substrate for magnetic field detection and thinly manufacturing the substrate of the signal processing circuit unit 10 for processing the signal transferred from the vertical hall device 20.

According to the preferred embodiment of the present invention, the substrate of the vertical hall device for detecting the horizontal magnetic field has the long gate length so as to have the sufficiently thick thickness, thereby improving the detection sensitivity of the horizontal magnetic field input to the vertical hall device.

Further, according to the preferred embodiment of the present invention, the substrate of the signal processing circuit for processing the signal transferred from the vertical hall device has the short gate so as to have the thin thickness, thereby saving the IC manufacturing cost while implementing the miniaturization due to the substrate having the smallest area and thickness.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A stacked type magnetic field detection sensor, comprising:
a vertical hall device including a first substrate of a thickness having a first gate length on which a first circuit pattern in a vertical direction is formed so as to sense magnetic field horizontally input and converting the magnetic field passing through circuit patterns in the vertical direction into a voltage signal; and
a signal processing circuit unit including a second substrate having a thickness having a second gate length on which a plurality of second circuit patterns are formed, to receive the voltage signal by stacking the vertical hall device thereon so as to detect a magnitude in the magnetic field according to the magnitude in the voltage and detecting the magnitude in the magnetic field by processing the voltage signal through the plurality of second circuit patterns.

2. The stacked type magnetic field detection sensor as set forth in claim 1, wherein the first gate length is 250 to 350 nm.

3. The stacked type magnetic field detection sensor as set forth in claim 1, wherein the second gate length is 90 to 180 nm.

4. The stacked type magnetic field detection sensor as set forth in claim 1, wherein the first substrate is made of a ferromagnetic material.

5. The stacked type magnetic field detection sensor as set forth in claim 1, wherein the plurality of second circuit patterns include:
a power supply circuit supplying power supply voltage;
a regulator stabilizing the power supply voltage supplied from the power supply circuit;
an oscillator supplied with the stabilized power supply voltage from the regulator to generate a clock signal having a period; and
a chopping circuit receiving the voltage signal from the vertical hall device operated by being supplied with the stabilized power supply voltage from the regulator and the clock signal generated from the oscillator to amplify a magnitude in the voltage signal having a period of the clock signal; and
an output load detecting output voltage according the voltage signal amplified from the chopping circuit to detect the magnitude in the magnetic field.

6. The stacked type magnetic field detection sensor as set forth in claim 5, wherein the plurality of second circuit patterns further include a Schmitt trigger circuit that is mounted between the chopping circuit and the output load to compare the amplified voltage signal with a threshold value so as to output the voltage signal as a high signal or a low signal.
